(19) United States
(12) Patent Application Publication
(10) Pub. No.: US 2025/0107406 A1
(43) Pub. Date: Mar. 27, 2025

(54) ELECTRONIC DEVICE

(71) Applicant: InnoLux Corporation, Miao-Li County (TW)

(72) Inventors: Yuan-Lin WU, Miao-Li County (TW); Kuan-Feng LEE, Miao-Li County (TW)

(73) Assignee: InnoLux Corporation, Miao-Li County (TW)

(21) Appl. No.: 18/809,290

(22) Filed: Aug. 19, 2024

(30) Foreign Application Priority Data
Sep. 26, 2023 (CN) 202311246307.5

(51) Int. Cl. H10K 59/80; H01L 25/16; H10K 77/10; H10K 102/00

(52) U.S. Cl. CPC H10K 59/8731; H10K 77/111; H01L 25/167; H10K 2102/311

(57) ABSTRACT

The present disclosure provides an electronic device including a flexible substrate, an electronic unit, and a cover. The flexible substrate has a first portion and a second portion. The electronic unit is disposed on the flexible substrate. The cover is disposed on the electronic unit and includes a first layer. The first layer is retreated from an edge of the first portion by a first distance and retreated from an edge of the second portion by a second distance, and the second distance is different from the first distance.

### BACKGROUND OF THE DISCLOSURE

### 1. Field of the Disclosure

The present disclosure relates to an electronic device and particularly to an electronic device with a flexible substrate.

### 2. Description of the Prior Art

Recently, electronic devices have been developed to have a flexible, foldable or bendable property, so that they can be applied to different kinds of objects. In the conventional flexible electronic device, an organic material is used as a cover of the flexible electronic device to maintain the flexibility. However, although the organic cover has the flexibility, an appearance or image displayed by the flexible electronic device must penetrate through the organic cover, so that the flexible electronic device has a problem of poor display quality.

### SUMMARY OF THE DISCLOSURE

It is an objective of the present disclosure to provide an electronic device.

According to an embodiment of the present disclosure, an electronic device is provided. The electronic device includes a flexible substrate, an electronic unit, and a cover. The flexible substrate has a first portion and a second portion. The electronic unit is disposed on the flexible substrate, and the cover is disposed on the electronic unit and includes a first layer. The first layer is retreated from an edge of the first portion by a first distance and retreated from an edge of the second portion by a second distance, and the second distance is different from the first distance.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a side view of an electronic device in a folded state according to a first embodiment of the present disclosure.

FIG. 2 schematically illustrates a top view of the electronic device in the flattened state according to the first embodiment of the present disclosure.

FIG. 3 schematically illustrates a cross-sectional view of an electronic device taken along a line A-A′ of FIG. 2 according to some embodiments of the present disclosure.

FIG. 4 schematically illustrates a cross-sectional view of an electronic device taken along a line B-B′ of FIG. 2 according to some embodiments of the present disclosure.

FIG. 5 schematically illustrates a cross-sectional view of an electronic device taken along a line C-C′ according to some embodiments of the present disclosure.

FIG. 6 schematically illustrates a cross-sectional view of an electronic device taken along a line D-D′ of FIG. 2 according to some embodiments of the present disclosure.

FIG. 7 schematically illustrates a cross-sectional view of the electronic device taken along a line E-E′ of FIG. 2 according to some embodiments of the present disclosure.

FIG. 8 schematically illustrates a cross-sectional view of an electronic device taken along the line A-A′ of FIG. 2 according to some embodiments of the present disclosure.

FIG. 9 schematically illustrates a side view of an electronic device installed on an object according to a second embodiment of the present disclosure.

FIG. 10 schematically illustrates a top view of the electronic device according to the second embodiment of the present disclosure in the flattened state.

FIG. 11 schematically illustrates a cross-sectional view taken along a line F-F′ of FIG. 10.

FIG. 12 schematically illustrates a cross-sectional view taken along a line G-G′ of FIG. 10.

FIG. 13 schematically illustrates a cross-sectional view of an electronic device taken along a line H-H′ of FIG. 10 according to some embodiments of the present disclosure.

FIG. 14 schematically illustrates a cross-sectional view of an electronic device taken along a line I-I′ of FIG. 10 according to some embodiments of the present disclosure.

FIG. 15 schematically illustrates a cross-sectional view of an electronic device taken along a line J-J′ of FIG. 10 according to some embodiments of the present disclosure.

FIG. 16 schematically illustrates a top view of an electronic device in the flattened state according to a third embodiment of the present disclosure.

FIG. 17 schematically illustrates cross-sectional views of the electronic device taken along a line K-K′ and a line L-L′ of FIG. 16 respectively according to the third embodiment of the present disclosure.

FIG. 18 schematically illustrates cross-sectional views of electronic devices in the flattened state according to some embodiments of the present disclosure.

FIG. 19 schematically illustrates cross-sectional views of parts of covers corresponding to one of the curve regions in the flattened state according to some embodiments of the present disclosure.

FIG. 20 schematically illustrates cross-sectional views of parts of covers corresponding to one of the curve regions in the flattened state according to some embodiments of the present disclosure.

FIG. 21 schematically illustrates cross-sectional views of parts of an electronic device in the flattened state respectively taken along a line K-K′ and a line M-M′ of FIG. 16 according to some embodiments of the present disclosure.

FIG. 22 schematically illustrates a top view of an electronic device in the flattened state according to a fourth embodiment of the present disclosure.

FIG. 23 schematically illustrates a side view of an electronic device according to a fifth embodiment of the present disclosure.

### DETAILED DESCRIPTION

The contents of the present disclosure will be described in detail with reference to specific embodiments and drawings. It is noted that, for purposes of illustrative clarity and being easily understood by the readers, the following drawings may be simplified schematic diagrams, and elements therein may not be drawn to scale. The numbers and sizes of the elements in the drawings are just illustrative and are not intended to limit the scope of the present disclosure.

Certain terms are used throughout the specification and the appended claims of the present disclosure to refer to specific elements. Those skilled in the art should understand that electronic equipment manufacturers may refer to an element by different names, and this document does not intend to distinguish between elements that differ in name but not function. In the following specification and claims, the terms “comprise”, “include” and “have” are open-ended fashion, so they should be interpreted as “including but not limited to . . . ”.

The ordinal numbers used in the specification and the appended claims, such as “first”, “second”, etc., are used to describe the elements of the claims. It does not mean that the element has any previous ordinal numbers, nor does it represent the order of a certain element and another element, or the sequence in a manufacturing method. These ordinal numbers are just used to make a claimed element with a certain name be clearly distinguishable from another claimed element with the same name.

Spatially relative terms, such as “above”, “on”, “beneath”, “below”, “under”, “left”, “right”, “before”, “front”, “after”, “behind” and the like, used in the following embodiments just refer to the directions in the drawings and are not intended to limit the present disclosure.

In addition, when one element or layer is “on” or “above” another element or layer or is “connected to” another element or layer, it may be understood that the element or layer is directly on the another element or layer, or directly connected to the another element or layer, and alternatively, another intervening element or layer may be between the element or layer and the another element or layer (indirectly). On the contrary, when the element or layer is “directly on” the another element or layer, or “directly connected to” the another element or layer, it may be understood that the element or layer and the another element or layer are electrically connected to each other without through another intervening element or layer. Also, the term “electrically connected” or “coupled” includes means of direct or indirect electrical connection.

As disclosed herein, the terms “approximately”, “essentially”, “about”, or “substantially” generally mean within 20%, 10%, 5%, 3%, 2%, 1%, or 0.5% of the reported numerical value or range. The quantity disclosed herein is an approximate quantity, that is, without a specific description of “approximately”, “essentially”, “about”, or “substantially”, the quantity may still include the meaning of “approximately”, “essentially”, “about”, or “substantially”.

It should be understood that according to the following embodiments, features of different embodiments may be replaced, recombined or mixed to constitute other embodiments without departing from the spirit of the present disclosure. The features of various embodiments may be mixed arbitrarily and used in different embodiments without departing from the spirit of the present disclosure or conflicting.

In the present disclosure, the length, thickness, width, height, distance, and area may be measured by using an optical microscope (OM), a scanning electron microscope (SEM) or other suitable methods, but not limited thereto.

Unless otherwise defined, all terms (including technical and scientific terms) used herein have the same meaning as commonly understood by those skilled in the art. It should be understood that these terms, such as those defined in commonly used dictionaries, should be interpreted as having meaning consistent with the relevant technology and the background or context of the present disclosure, and should not be interpreted in an idealized or excessively formal way, unless there is a specific definition in the embodiments of the present disclosure.

According to embodiments of the present disclosure, an electronic device may include a display device, a tiled device, a touch device, a sensing device, a curved electronic device or a non-rectangular electronic device, but not limited thereto. The electronic device may, for example, include liquid crystal, a light-emitting diode, a fluorescent material, a phosphor material, other suitable display mediums, or any combination thereof, but not limited thereto. The electronic device may include an electronic unit, and the electronic unit may be a passive element or active element, such as a capacitor, a resistor, an inductor, a diode, a transistor, etc. The diode may include a light-emitting diode (LED) or a photodiode. The light-emitting diode may, for example, an organic light-emitting diode (OLED), a mini LED, a micro LED or a quantum dot LED, but not limited thereto. The tiled device may, for example, a tiled display device. It is noted that the electronic device of the present disclosure may be any combination of the above-mentioned devices, but not limited thereto. Furthermore, the electronic device may be bendable or flexible electronic device, but not limited thereto. The appearance of the electronic device may be rectangular, circular, polygonal, a shape with curved edges or other suitable shapes, but not limited thereto. The electronic device may have a peripheral system, such as a driving system, a control system, a light source system, a shelf system, etc., for supporting display device or tiled device. For convenience, a display device is taken as an example of the electronic device to describe the present disclosure in the following contents, but the present disclosure is not limited thereto.

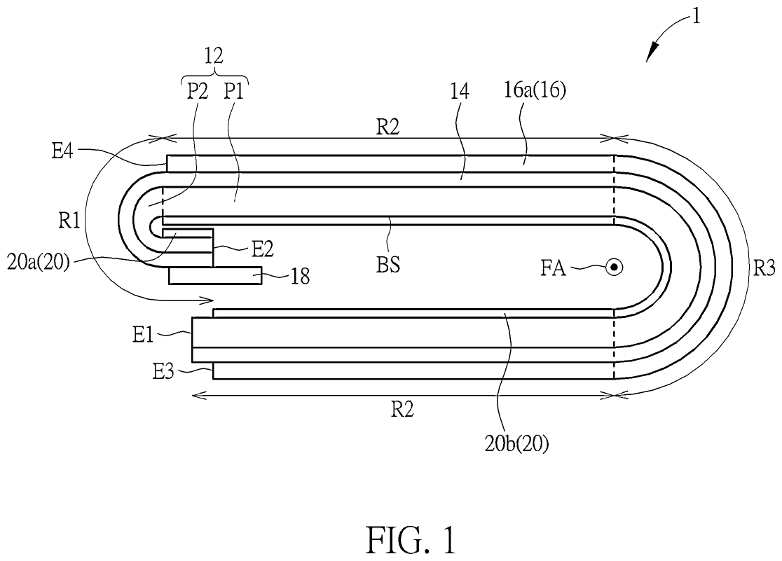

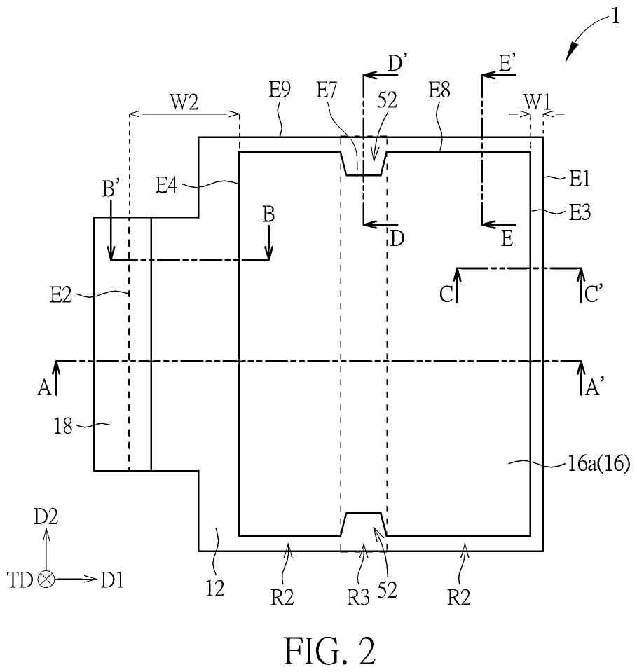

FIG. 1 schematically illustrates a side view of an electronic device in a folded state according to a first embodiment of the present disclosure, and FIG. 2 schematically illustrates a top view of the electronic device in the flattened state according to the first embodiment of the present disclosure. As shown in FIG. 1 and FIG. 2, the electronic device 1 includes a flexible substrate 12, an electronic unit 14, and a cover 16. The flexible substrate 12 may have a first portion P1 and a second portion P2. The electronic unit 14 is disposed on the flexible substrate 12, and the cover 16 is disposed on the electronic unit 14. Also, the cover 16 includes a first layer 16a, wherein the first layer 16a is retreated from an edge E1 of the first portion P1 by a distance W1 and retreated from an edge of the second portion P2 by a distance W2. For example, the distance W1 may be a distance between the edge E3 of the first layer 16a corresponding to the edge E1 of the first portion P1 and the edge E1 of the first portion P1 in the flattened state of the electronic device 1, and the distance W2 may be a distance between another edge E4 of the first layer 16a corresponding to the edge E2 of the second portion P2 and the edge E2 of the second portion P2 in the flattened state of the device 1. The distance W2 may be different from the first distance W1, so that stress on the first layer 16a may be decreased to reduce crack damage to the first layer 16a during manufacturing processes of the electronic device or during use by a user. In order to clearly illustrate a relationship between the flexible substrate 12 and the cover 16, the electronic unit 14 is omitted in FIG. 2, but not limited thereto.

The first portion P1 and the second portion P2 may be any two portions of the flexible substrate 12. In one embodiment, the first portion P1 may be a non-bending portion of the flexible substrate 12, and the second portion P2 is a portion of the flexible substrate 12 that is bent to a backside BS of the first portion P1 relative to the first portion P1. In some embodiments, when the second portion P2 is bent to the backside BS of the first portion P1 during the electronic device 1 being in use, the distance W1 and the distance W2 may be distances measured along the same direction (e.g., a first direction) as the electronic device 1 is in the flattened state. It should be noted that the first portion P1 may be folded along a folding axis FA, so that a part of the first portion P1 may be folded to the backside BS of the first portion P1. In the present disclosure, the terms “bent” and “folded” have different meanings, wherein a radius of curvature of a bending region R1 is less than a radius of curvature of a folding region R3.

In one embodiment, the electronic device 1 may further include a circuit board 18 bonded to the second portion P2, but not limited thereto. The circuit board 18 may, for example, be adjacent to the edge E2 of the second portion P2 and be electrically connected and bonded to the electronic unit 14 disposed on the second portion P2. While assembling the electronic device 1, the second portion P2 of the flexible substrate 12 may be bent to the backside BS of the first portion P1, so that the second portion P2 may include a bending region R1. A part of the electronic unit 14 disposed on the second portion P2 may be bent to the backside BS of the first portion P1 along with the second portion P2, so that a width of the electronic device 1 formed by the second portion P2 may be reduced, or a border width of the electronic device 1 may be decreased. In the present disclosure, the second portion P2 bent to the backside BS of the first portion P1 may mean that at least a part of the second portion P2 overlaps the first portion P1 in a top view direction TD of the electronic device 1.

The backside BS of the first portion P1 may be, for example, a side of the first portion P1 opposite to the cover 16. In order to reduce crack damage to the first layer 16a when the second portion P2 is bent to the backside BS of the first portion P1, the distance W2 may be greater than the distance W1. A ratio of the distance W2 to the distance W1 may be, for example, ranged from 1.5 to 1000 (i.e., 1.5≤the ratio of the distance W2 to the distance W1≤1000). It should be noted that if the ratio of the distance W2 to the distance W1 is too small, that is, when the distance W1 is close to the distance W2, the edge E4 of the first layer 16a adjacent to the circuit board 18 is subjected to greater stress when the second portion P2 is bent to the backside BS of the first portion P1, or the edge E3 of the first layer 16a away from the circuit board 18 may be too far away from the edge E1 of the first portion P1, so that the first layer 16a cannot provide sufficient protection for the electronic unit 14. If the ratio of the distance W2 to the distance W1 is too large, the edge E4 of the first layer 16a adjacent to the circuit board 18 cannot provide sufficient protection for the electronic unit 14. The distance W1 may, for example, be greater than or equal to 0.03 mm and less than or equal to 0.6 mm (i.e., 0.03 mm≤the distance W1≤0.6 mm). The distance W2 may, for example, be greater than or equal to 1 millimeter (mm) and less than or equal to 30 mm (i.e., 1 mm≤the distance W2≤30 mm). In one embodiment, a difference between the distance W2 and the distance W1 may be, for example, greater than or equal to 0. 4 millimeters (mm) and less than or equal to 30 mm (i.e., 0.4 mm≤the difference between the distance W2 and the distance W1≤30 mm). In this case, the electronic device 1 may be applied to a handheld device, such as a mobile phone, a tablet or other suitable devices, but not limited thereto. The circuit board 18 may include, for example, a flexible circuit board or other suitable circuit elements. In some embodiments, chips or other suitable elements may be optionally provided on the circuit board 18, but not limited thereto.

As shown in FIG. 1, the first portion P1 may include at least one non-folding region R2 and a folding region R3, wherein the folding region R3 is disposed on a side of the non-folding region R2, so that the electronic device 1 may be a foldable device, but not limited thereto. In one embodiment, the number of non-folding regions R2 may be two, and the folding region R3 may be located between the non-folding regions R2. The bending region R1 may be connected to a side of the non-folding region R2 opposite to the folding region R3, but not limited thereto. In the embodiment of FIG. 1, the folding region R3 may, for example, extend along the second direction D2, so that the electronic device 1 may be folded along the folding axis FA parallel to the second direction D2. The second direction D2 may be, for example, perpendicular to the first direction D1. In the present disclosure, the folding region R3 may be defined as a portion of the flexible substrate 12 where is folded when the electronic device 1 is in the folded state, the non-folding region R2 may be defined as another portion of the flexible substrate 12 where is flattened when the electronic device 1 is in the folded state, and the folding region R3 is disposed between the two non-folding regions R2.

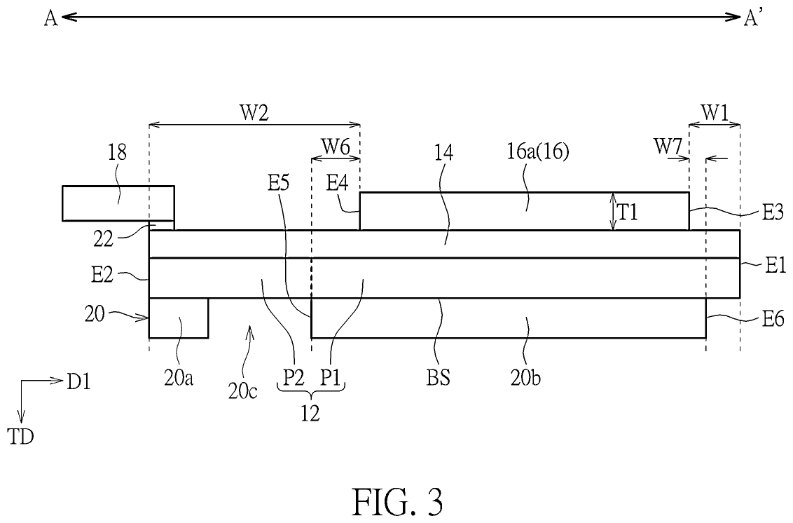

The cover 16 may be a single-layer structure or a multi-layer structure. As shown in FIG. 1 and FIG. 2, when the cover 16 is the single-layer structure, the cover 16 may be formed of the first layer 16a, but not limited thereto. The first layer 16a may, for example, include glass or other suitable inorganic materials for improving display quality of the electronic device 1. In this embodiment, the first layer 16a may be glass, but not limited thereto. A thickness of the first layer 16a (e.g., a thickness T1 shown in FIG. 3) may be, for example, less than or equal to 100 micrometers (μm), so that the first layer 16a may have a flexible or foldable property. It is noted that when cracks occur at an edge of glass with a thickness less than 100 μm, the glass is easily fragmented in large area. Through retreating the first layer 16a from the edge E1 of the first portion P1 by the distance W1 and from the edge E2 by the distance W2, occurrence of cracks in the first layer 16a may be decreased. Furthermore, since the distance W1 is less than the distance W2, cracks in the first layer 16a due to the bending of the second portion P2 may be further reduced, so as to reduce crack damage to the first layer 16a. When the crack damage to the first layer 16a is reduced, the first layer 16a may be allowed to be disposed in the electronic device 1, so as to improve the display quality of the electronic device 1.

The electronic unit 14 may include any type of electronic element. For example, the electronic element may include a display element, a light-emitting element, a sensing element, an antenna, or other types of elements. The electronic unit 14 of this embodiment may refer to the embodiments of the following contents, but not limited thereto.

In this embodiment, the electronic device 1 may optionally further include a supporting film 20 disposed on the backside BS of the flexible substrate 12 opposite to the electronic unit 14, but not limited thereto. The supporting film 20 may be flexible and have a greater hardness than the flexible substrate 12. For example, the supporting film 20 and the flexible substrate 12 may include the same material, and in this case, the thickness of the supporting film 20 may be greater than the thickness of the flexible substrate 12. Alternatively, the support film 20 and the flexible substrate 12 may include different materials. The support film 20 and the flexible substrate 12 may each include an organic material. The organic material may include, for example, polyimide (PI), polycarbonate (PC), polyethylene terephthalate (PET), poly (methyl methacrylate) (PMMA), rubber, acrylonitrile butadiene styrene (ABS), other suitable materials, or any combination of the above materials. In FIG. 1, the thickness of the supporting film 20 and the thickness of the flexible substrate 12 are illustrative and not limited thereto.

FIG. 3 schematically illustrates a cross-sectional view of an electronic device taken along a line A-A′ of FIG. 2 according to some embodiments of the present disclosure. As shown in FIG. 3, in some embodiments, the supporting film 20 may optionally include a block 20a and a block 20b separated from each other, and a gap 20c between the block 20a and the block 20b may overlap the bending region R1 in the top view direction TD of the electronic device 1, so that the stress generated by the supporting film 20 on the first layer 16a may be reduced when a part of the electronic device 1 corresponding to the bending region R1 is bent. Accordingly, the crack damage to the first layer 20 may be reduced.

In the embodiment of FIG. 3, the block 20a may be disposed on a side of the second portion P2 opposite to the electronic unit 14. In the case that the electronic device 1 is in the flattened state, the block 20a may overlap a part of the circuit board 18 in the top view direction TD. The block 20a may be used to support a part of the second portion P2 as well as the electronic unit 14 and the circuit board 18 thereon.

The block 20b may be disposed on a side of the first portion P1 opposite to the electronic unit 14 to carry the electronic unit 14 on the first portion P1. As viewed along the top view direction TD of the electronic unit 1, the first layer 16a may be retreated from the edge E5 of the block 20b adjacent to the circuit board 18 by a distance W6, and the first layer 16a may be retreated from the edge E6 of the block 20b away from the circuit board 18 by a distance W7. The distance W6 may be greater than the distance W7, such that when the second portion P2 is bent to the backside BS of the first portion P1, the stress on the edge E4 of the first layer 16a may be decreased to reduce damage to the first layer 16a. A ratio of the distance W6 to the distance W7 may, for example, be greater than 1 and less than or equal to 10 (i.e., 1<the ratio of the distance W6 to the distance W7≤10). For instance, the distance W6 may be greater than 30 μm and less than or equal to 10,000 μm (i.e., 30 μm<the distance W6≤10,000 μm), and the distance W7 may be greater than or equal to 30 μm and less than or equal to 1,000 μm (i.e., 30 μm≤the distance W7≤1,000 μm). In one embodiment, a difference between the distance W6 and the distance W7 may be, for example, greater than 0 μm and less than or equal to 2000 μm (i.e., 0 μm<the difference between the distance W6 and the distance W7≤2000 μm), but not limited thereto. When the distance W6 is greater than 0 μm, friction between the first layer 16a and housing during assembling process may be avoided, which reduces the occurrence of damage to the first layer 16a.

It should be noted that, as shown in FIG. 3, the distance W1 and/or the distance W2 may be greater than the thickness T1 of the first layer 16a to reduce damage to the first layer 16a. For example, the thickness T1 of the first layer 16a may be greater than or equal to 5 μm and less than or equal to 100 μm (i.e., 5 μm≤the thickness T1 of the first layer 16a≤100 μm). The distance W1 may, for example, be greater than or equal to 30 μm and less than or equal to 600 μm (i.e., 30 μm≤the distance W1≤600 μm) or greater than or equal to 50 μm and less than or equal to 400 μm (i.e., 50 μm≤the distance W1≤400 μm). It should be noted that when the electronic device 1 is in the flattened state, the thickness T1 of the first layer 16a at different positions may be substantially uniform. In this case, the thickness T1 of the first layer 16a may be measured at any position of the electronic device 1 except measured at the edge of the electronic device 1.

In addition, as shown in FIG. 3, the circuit board 18 may be electrically connected to the electronic unit 14 through a pad 22. The pad 22 in FIG. 3 is exemplary, but not limited thereto. In some embodiments, the pad 22 may be disposed in the electronic unit 14, for example. The embodiments described above or below may be used as the reference of other parts of the electronic device in FIG. 3 which will not be described in detail here.

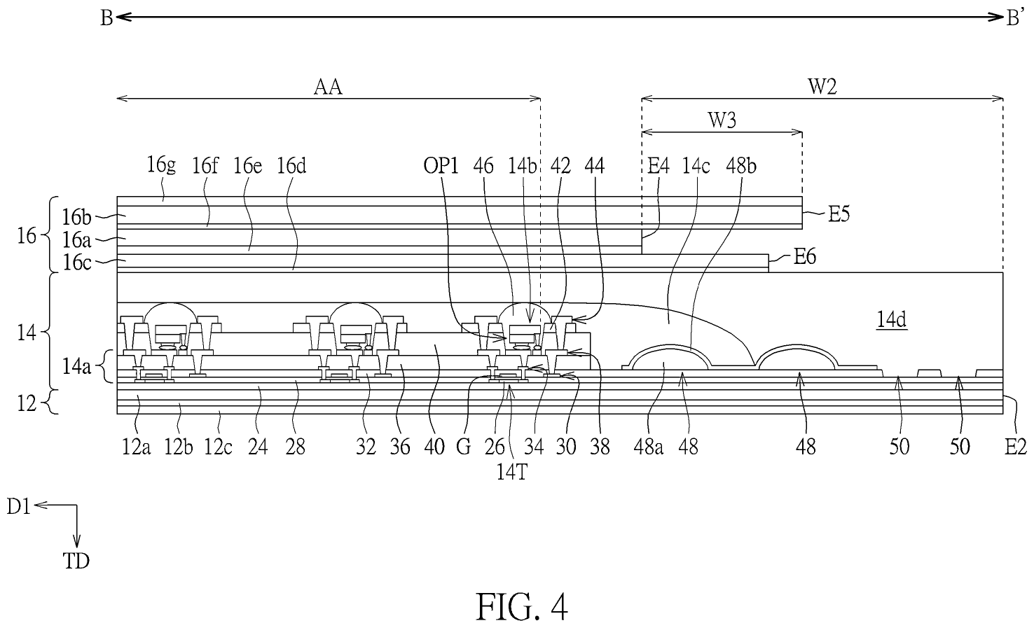

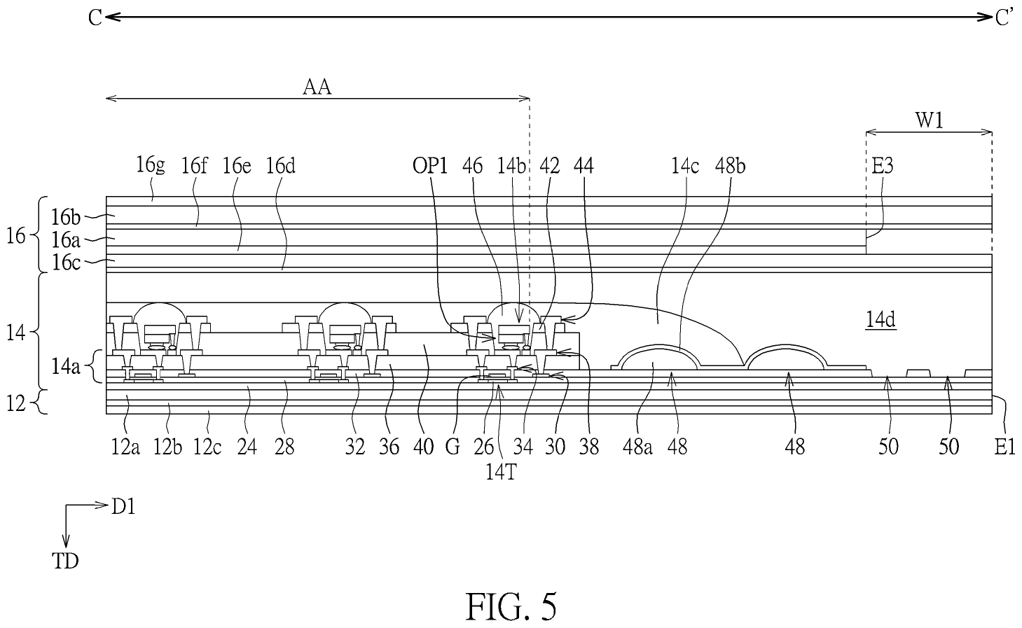

FIG. 4 schematically illustrates a cross-sectional view of an electronic device taken along a line B-B′ of FIG. 2 according to some embodiments of the present disclosure, and FIG. 5 schematically illustrates a cross-sectional view of an electronic device taken along a line C-C′ according to some embodiments of the present disclosure. As shown in FIG. 4 and FIG. 5, in some embodiments, the cover 16 may further include a second layer 16b disposed on the first layer 16a. In the embodiment of FIG. 4 and FIG. 5, the cover 16 may further include a third layer 16c disposed under the first layer 16a, but not limited thereto.

Since the first layer 16a is disposed between the second layer 16b and the third layer 16c, the first layer 16a may be protected by the second layer 16b and the third layer 16c. The first layer 16a may include an inorganic material, and the second layer 16b and the third layer 16c may include an organic material, but not limited thereto. The second layer 16b and the third layer 16c may include, for example, PI, PC, PET, PMMA, rubber, ABS or other suitable materials.

As shown in FIG. 4 and FIG. 5, the cover 16 may further include an adhesive 16d, an adhesive 16e, and an adhesive 16f, wherein the second layer 16b is attached to the first layer 16a through the adhesive 16f, the third layer 16c is attached to the first layer 16a through the adhesive 16e, and the third layer 16c may be attached to the electronic unit 14 through the adhesive 16d, but the present disclosure is not limited thereto. The adhesive 16d, the adhesive 16e, and the adhesive 16f may, for example, include an acrylate material or other suitable materials.

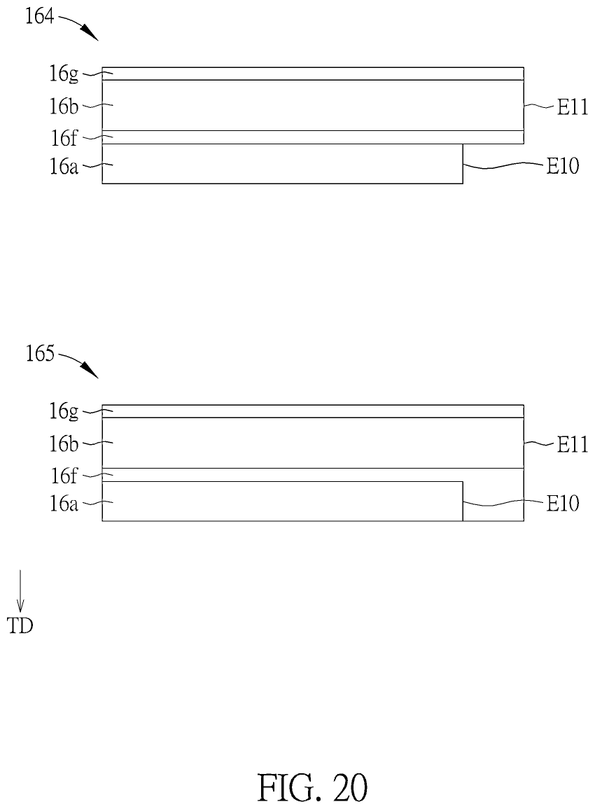

In some embodiments, the cover 16 may optionally not include the third layer 16c (e.g., as shown in FIG. 20) or not include both the second layer 16b and the third layer 16c (e.g., as shown in FIG. 1 or FIG. 3), but not limited thereto. In this case, the cover 16 may optionally not include the adhesive 16d or both the adhesive 16d and the adhesive 16f.

In the embodiment of FIG. 4 and FIG. 5, the edge E4 of the first layer 16a may not be aligned to the edge of the second layer 16b adjacent to the edge E4 in the top view direction TD. In this case, the first layer 16a may be retreated from the edge E5 of the second layer 16b by a distance W3, and the distance W3 may, for example, range from 30 μm to 600 μm (i.e., 30 μm≤the first distance W1≤600 μm), such that the edge E4 of the first layer 16a may be protected by the second layer 16b during manufacturing processes (e.g., an assembling process or other processes) or during use to reduce cracks. In some embodiments, the edge E5 of the second layer 16b may or may not be aligned to the edge E2 of the flexible substrate 12 in the top view direction TD, but not limited thereto. In some embodiments, the edge E4 of the first layer 16a may or may not be aligned to the edge E6 of the third layer 16c adjacent to the edge E4 in the top view direction TD, and the first layer 16a may be retreated from the edge E6 of the third layer 16c by a distance, but not limited thereto.

In some embodiments, the edge E4 of the first layer 16a, the edge E5 of the second layer 16b adjacent to the edge E4, and the edge E6 of the third layer 16c adjacent to the edge E2 may not be aligned to each other in the top view direction TD, but not limited thereto. In some embodiments, at least two of the edge E4 of the first layer 16a, the edge E5 of the second layer 16b adjacent to the edge E4, and the edge E6 of the third layer 16c adjacent to the edge E4 may be aligned to each other in the top view direction TD. In some embodiments, the edge E6 of the third layer 16b may or may not be aligned to the edge E2 of the flexible substrate 12 in the top view direction TD, but not limited thereto.

In some embodiments, at least one edge of the third layer 16c may be aligned to a corresponding edge of the adhesive 16d in the top view direction TD, at least one edge of the first layer 16a may be aligned to a corresponding edge of the adhesive 16e in the top view direction TD, and/or at least one edge of the second layer 16b may be aligned to a corresponding edge of the adhesive 16f in the top view direction TD, but not limited thereto. In some embodiments, the edge of the first layer 16a may not be aligned to the corresponding edge of the adhesive 16e, and/or the edge of the second layer 16b may not be aligned to the corresponding edge of the adhesive 16f.

In some embodiments, the cover 16 may optionally include a coating layer 16g disposed on the second layer 16b to protect elements and layers below the coating layer 16g. The coating layer 16g may include an organic material, such as PMMA, PC or other suitable materials. The thickness of the coating layer 16g may be, for example, less than 10 μm. In some embodiments, the coating layer 16g may be, for example, a hard coating layer.

The flexible substrate 12 may be a single-layer structure or a multi-layer structure. As shown in FIG. 4, the flexible substrate 12 may, for example, be the multi-layer structure and include a first substrate 12a, an inorganic layer 12b, and a second substrate 12c, wherein the inorganic layer 12b is sandwiched between the first substrate 12a and the second substrate 12c, such that the flexible substrate 12 has a function of blocking water and/or oxygen, but not limited thereto. The first substrate 12a and the second substrate 12c may, for example, include an organic material. The inorganic layer 12b may, for example, include silicon oxide, silicon nitride, or other suitable materials. In some embodiments, the flexible substrate 12 may be formed of the organic material when the flexible substrate 12 is the single-layer structure, but not limited thereto.

As shown in FIG. 4 and FIG. 5, the electronic unit 14 may include a circuit layer 14a and a plurality of electronic elements 14b. The circuit layer 14a may be disposed on the flexible substrate 12, and the electronic elements 14b may be disposed on the circuit layer 14a and coupled to the circuit layer 14a. The circuit layer 14a may be, for example, a layer including active elements or passive elements for receiving external signals and driving the electronic elements 14b according to the external signals. Accordingly, the electronic elements 14b may output, such as emitting light or emitting radio frequency electromagnetic waves. One of the electronic elements 14b may include, for example, a light-emitting element or other suitable elements. The light-emitting element may include, for example, an inorganic light-emitting diode or an organic light-emitting diode, but not limited thereto. In this content, the light-emitting element is taken as an example of the electronic element 14b, but not limited thereto. In this case, when viewed along the top view direction TD, a distribution region of the electronic elements 14b may serve as a display region AA. In some embodiments, the electronic elements 14b may include an optical sensor, a blood oxygen detector, a heartbeat detector, a blood pressure detector, a diode, other suitable elements, or any combination thereof, but the present disclosure is not limited thereto.

In some embodiments, the electronic unit 14 may optionally further include an insulating layer 24 disposed between the flexible substrate 12 and the circuit layer 14a. The insulating layer 24 may, for example, serve as a buffer layer of the electronic device 1 to mitigate the influence of moisture and/or oxygen on the circuit layer 14a and/or the electronic elements 14b.

For example, the circuit layer 14a may further include a plurality of transistors 14T, and at least one of the transistors 14T may be coupled to at least one of the electronic elements 14b and serve as a driving element and/or a switching element of one of the electronic elements 14b, but not limited thereto. In FIG. 4, the electronic elements 14b may be coupled to the corresponding transistors 14T respectively, but not limited thereto. The circuit layer 14a may include at least one semiconductor layer, a plurality of insulating layers, and a plurality of conductive layers to form the transistors 14T, signal lines, traces, capacitors, electrodes, and/or other circuit elements. In the embodiment of FIG. 4, the insulating layers may include an insulating layer 28, an insulating layer 32, and an insulating layer 36, and the conductive layers may include a conductive layer 30, a conductive layer 34, and a conductive layer 38, and the insulating layer 28, the conductive layer 30. The insulating layer 28, the conductive layer 30, the insulating layer 32, the conductive layer 34, the insulating layer 36 and the conductive layer 38 may be formed sequentially, but not limited thereto. The insulating layer 32 and the insulating layer 36 may, for example, have through holes, such that electrodes of the conductive layer be electrically connected to the corresponding transistors 14T through the through holes of the insulating layer 32, and electrodes of the conductive layer 38 may be electrically connected to the corresponding electrodes of the conductive layer 34 through the through holes of the insulating layer 36 and/or electrically connected to the corresponding electrodes of the conductive layer 30 through the through holes of the insulating layer 32 and the insulating layer 36, but not limited thereto. The numbers of the insulating layers and the conductive layers and layout structure of the conductive layers are not limited to FIG. 4 and may be adjusted according to requirements. The structure of the circuit layer 14 shown in FIG. 4 is exemplary, and the present disclosure is not limited thereto.

In the circuit layer 14 of FIG. 4 and FIG. 5, a top-gate type thin film transistor is used as an example of the transistor 14T, but not limited thereto. In this case, the transistor 14T may include a gate G and a semiconductor 26. Two end parts of the semiconductor 26 may be doped with dopants to serve as a source region and a drain region, respectively, and a part of the semiconductor 26 disposed between the source region and the drain region may serve as a channel region of the transistor 14T. The insulating layer 28 may serve as a gate insulating layer of the transistor 14T. For example, the material of the semiconductor 26 may include silicon or metal oxide and may be low temperature poly-silicon (LTPS) semiconductor, amorphous silicon (a-Si) semiconductor, indium gallium zinc oxide (IGZO) semiconductor, or other suitable semiconductors, but not limited thereto. In some embodiments, the semiconductors 26 of different transistors 14T may include different materials. For example, the semiconductor 26 of one of the transistors 14T may include low-temperature polysilicon semiconductor, and the semiconductor 26 of another of the transistors 14T may include metal-oxide semiconductor, but not limited thereto.

In some embodiments, the electronic unit 14 may further include an insulating layer 40 and an insulating layer 42 sequentially disposed on the circuit layer 14a, and the insulating layer 40 and the insulating layer 42 may have a plurality of openings OP1 for respectively disposing corresponding electronic elements 14b therein. For example, the opening OP1 may be used to define a position of a pixel or sub-pixel of the electronic device 1, and the insulating layer 40 may be known as a pixel definition layer, but not limited thereto. In some embodiments, the electronic unit 14 may optionally not include the insulating layer 42, but not limited thereto.

In one embodiment, the electronic unit 14 may further include a conductive layer 44 disposed on the insulating layer 42. The electrodes or traces of the conductive layer 44 may, for example, be used to electrically connect elements in the circuit layer 14a to external elements or to electrically connect different portions of the circuit layer 14a to each other, but not limited thereto. In some embodiments, the electronic unit 14 may optionally further include a plurality of protecting members 46 respectively disposed on corresponding electronic elements 14b to protect the electronic elements 14b. The protecting members 46 may, for example, be respectively disposed in the corresponding openings OP1, but not limited thereto. The protecting members 46 may include, for example, optical glue, UV curing adhesive, or other suitable materials.

In some embodiments, the insulating layer 24, the insulating layer 28, the insulating layer 32, the insulating layer 36, the insulating layer 40, and/or the insulating layer 42 may include a single-layer structure or a multi-layer structure and may include any suitable organic material or inorganic material. The organic material may include, for example, PMMA, epoxy, siloxane material, silica gel material, other suitable materials, or any combination thereof. The inorganic material may include silicon nitride, silicon oxide, liquid glass, glass glue, titanium oxide, aluminum oxide, other suitable materials, or any combination thereof. In some embodiments, when each of the insulating layer 24, the insulating layer 28, the insulating layer 32, the insulating layer 36, the insulating layer 40, and the insulating layer 42 is the multi-layer structure, they may each include a structure of stacking multilayered inorganic materials or multilayered organic materials or a structure of alternately stacking the inorganic materials and the organic materials, but the present disclosure is not limited thereto. The conductive layer 30, the conductive layer 34, the conductive layer 38, and the conductive layer 44 may each include metal or other suitable conductive materials.

As shown in FIG. 4, the electronic unit 14 may further include an encapsulation layer 14c disposed over the circuit layer 14a and the electronic elements 14b to reduce the influence of moisture and/or oxygen on the electronic elements 14b and the transistors 14T, the electrodes and/or the traces of the circuit layer 14a. The encapsulation layer 14c may include a single-layer structure or a multi-layer structure and may include any suitable organic or inorganic material. The encapsulation layer 14c may, for example, include PI or other suitable materials. In some embodiments, the electronic unit 14 may further include a planarization layer 14d disposed on the encapsulation layer 14c and having a flat upper surface to facilitate adhering to the cover 16. The planarization layer 14d may, for example, include an organic material or other suitable materials.

It is to be noted that in some embodiments, a part of the planarization layer 14d adjacent to the edge E2 of the flexible substrate 12 may be removed to expose pads (not shown) of the circuit layer 14a, such that a circuit board (e.g., the circuit board 18 shown in FIG. 1 or FIG. 2) may be electrically connected and bonded to the pad to be further electrically connected to other elements in the circuit layer 14a. The electronic device 1 may optionally further include an encapsulant disposed on the bonding between the circuit board 18 and the pad, but not limited thereto. The structure of the circuit board and the pad are omitted in FIG. 4 in order to clearly show the electronic units 14, but not limited thereto.

As shown in FIG. 4 and FIG. 5, the electronic unit 14 may, for example, include at least one dam structure 48 disposed between an edge (e.g., the edge E2) of the flexible substrate 12 and the electronic elements 14b in the top view direction TD and used to block overflow of the encapsulation layer 14c to an outer side of the dam structure 48 during forming the encapsulation layer 14c. As viewed in the top view direction TD, the dam structure 48 may, for example, surround the transistors 14T of the circuit layer 14a and the electronic elements 14b. In the embodiment of FIG. 4, the electronic unit 14 may include two dam structures 48 sequentially arranged between the electronic elements 14b and the edge of the flexible substrate 12. One of the dam structures 48 may, for example, include a stack of an organic layer 48a and an inorganic layer 48b. The organic layer 48a may, for example, include the same material, be formed by the same process, or be formed of the same organic layer as one of the layers in the electronic unit 14. The inorganic layers 48b of different dam structures 48 may, for example, be connected to each other, but not limited thereto. In some embodiments, the inorganic layer 48b may, for example, include a single-layer structure or a multi-layer structure. In some embodiments, the electronic unit 14 may include different layers and elements based on types of electronic device 1. In some embodiments, the number of the dam structures 48 is not limited to FIG. 4 and may be at least one.

In some embodiments, the electronic unit 14 may optionally further include crack stop structures 50 disposed in the insulating layer of the electronic unit 14. The crack stop structures 50 may be used to prevent cracks in the insulating layers of the electronic unit 14 at edges from extending into the display region AA. As viewed along the top view direction TD, the crack stop structures 50 may be provided between the dam structures 48 and an edge (e.g., the edge E1 or the edge E2) of the flexible substrate 12. The crack stop structure 50 may be, for example, a groove or a through hole that extends into at least one insulating layer adjacent to the edge of the flexible substrate 12, wherein the groove may refer to a structure that does not penetrate through the insulating layer, and the through hole may refer to a structure that penetrates through the insulating layer. In FIG. 4, the crack stop structure 50 may be the through hole in the insulating layer 32, but not limited thereto. In some embodiments, the crack stop structure 50 may, for example, penetrate through the insulating layer 32 and the insulating layer 28 or through the insulating layer 32, the insulating layer 28, and the insulating layer 24, but not limited thereto. In FIG. 4 and FIG. 5, the planarization layer 14d may optionally be disposed in the crack stop structures 50. In some embodiments, the number of crack stop structures 50 is not limited to FIG. 4 and may be at least one.

It is noted that the first layer 16a may cover the display region AA in the top view direction TD, so that abnormal quality at an edge of an image displayed by the electronic device 1 may be mitigated. In FIG. 4 and FIG. 5, the first layer 16a may partially overlap or cover the dam structure 48 in the top view direction TD to reduce damage to the dam structures 48, thereby improving the protection of the circuit layer 14a and the electronic elements 14b. In some embodiments, the first layer 16a may not overlap the crack stop structures 50 in the top view direction TD, but not limited thereto. In some embodiments, the first layer 16a may overlap both the dam structures 48 and the crack stop structures 50, but not limited thereto. In some embodiments, other parts of the electronic device in FIGS. 4 and 5 may adopt the above-mentioned or following embodiments and will not be described in detail here.

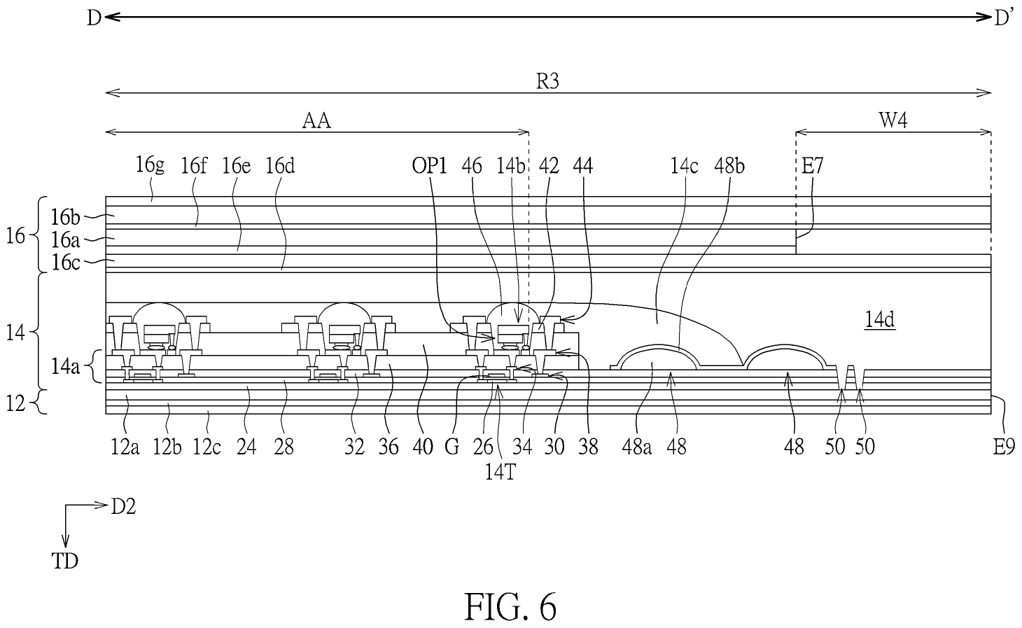

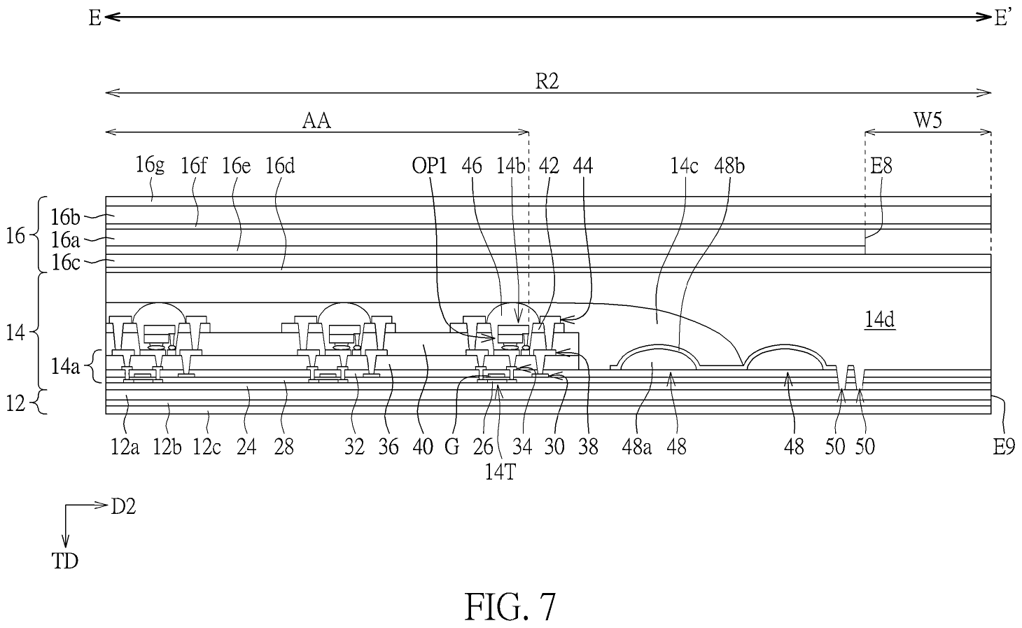

FIG. 6 schematically illustrates a cross-sectional view of an electronic device taken along a line D-D′ of FIG. 2 according to some embodiments of the present disclosure, and FIG. 7 schematically illustrates a cross-sectional view of the electronic device taken along a line E-E′ of FIG. 2 according to some embodiments of the present disclosure. As shown in FIG. 2, a structure shown in FIG. 6 is a part of the electronic device 1 corresponding to the folding region R3, and a structure shown in FIG. 7 is a part of the electronic device 1 corresponding to a non-folding region R2. The first layer 16a may have at least one recess 52 disposed on the folding region R3 and facing the edge E9 of the flexible substrate 12, which may reduce cracks of a part of the first layer 16a disposed on the folding region R3 when the electronic device 1 is folded. In this embodiment, the first layer 16a may have two recesses 52 facing two opposite edges E9 of the flexible substrate 12.

As shown in FIG. 6 and FIG. 7, the first layer 16a is retreated from the edge E9 of the folding region R3 by a distance W4 and from the edge E9 of the non-folding region R2 by a distance W5, wherein the distance W4 is greater than the distance W5. In other words, as viewed from the top view direction TD, the distance W4 between the edge E7 of the folding region R3 and the edge E8 of the first layer 16a disposed on the folding region R3 may be greater than the distance W5 between the edge E7 of the non-folding region R2 and the edge E9 of the first layer 16a disposed on the non-folding region R2.

In FIG. 6, an edge of the first layer 16a may not be aligned to a corresponding edge of the adhesive 16e, but not limited thereto. In some embodiments of FIG. 6 and FIG. 7, an edge of the second layer 16b adjacent to the edge E9 of the folding region R3 may be aligned to or not aligned to the edge E9 in the top view direction TD, but not limited thereto. In some embodiments, an edge of the third layer 16c adjacent to the edge E9 of the folding region R3 may be aligned to or not aligned to the edge E9 of the folding region R3 in the top view direction TD, but not limited thereto. In some embodiments, the first layer 16a may not have the recess 52, but not limited thereto. In some embodiments, other parts of the electronic device of FIG. 6 and FIG. 7 may use any one of the above-mentioned or following embodiments and will not be described herein.

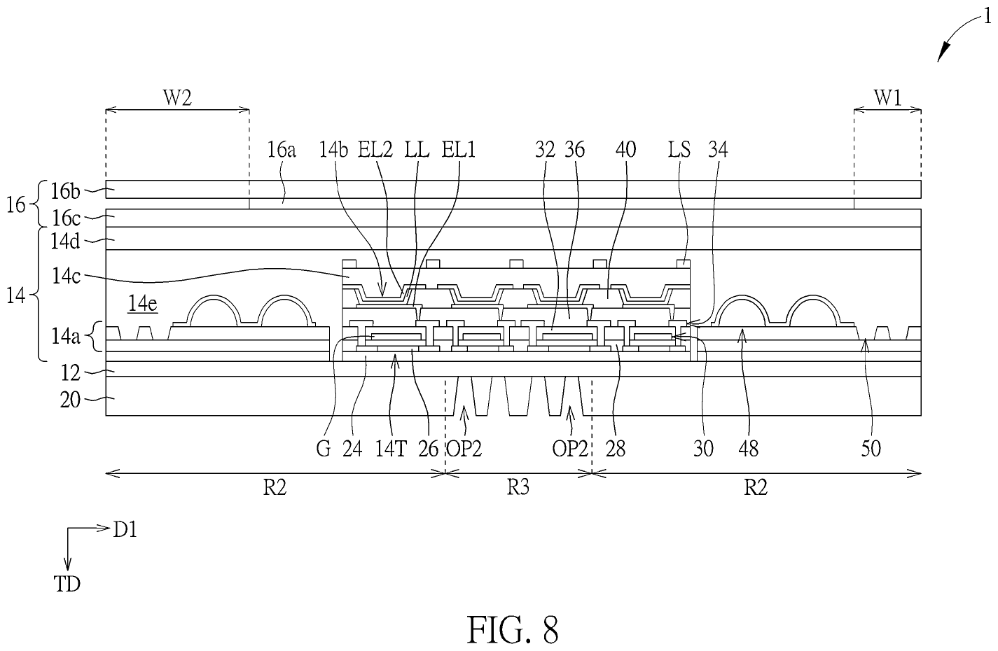

Refer to FIG. 8, which schematically illustrates cross-sectional view of an electronic device taken along the line A-A′ of FIG. 2 according to some embodiments of the present disclosure. As shown in FIG. 8, the flexible substrate 12 may include the folding region R3 and the non-folding regions R2. For clarity, the circuit board and the bending region are omitted in FIG. 8, but not limited thereto. In the embodiment of FIG. 8, the supporting film 20 may have an opening OP2 that overlaps the folding region R3 of the flexible substrate 12 in the top view direction TD. The opening OP2 may reduce the stress on the part of the electronic device 1 corresponding to the folding region R3 when the electronic device 1 is folded. In some embodiments, the first layer 16a may overlap the opening OP2 in the top view direction TD, so as to improve uniformity of display quality of the electronic device 1.

In the embodiment of FIG. 8, each electronic element 14b may include an organic light-emitting diode, but not limited thereto. For example, the electronic element 14b may include an electrode EL1, a light-emitting layer LL, and an electrode EL2, which are sequentially disposed on the insulating layer 36. The electrode EL1 may be electrically connected to an electrode of the conductive layer 34 through a through hole of the insulating layer 36, so as to be electrically connected to the corresponding transistor 14T. In some embodiments, the electrodes EL2 of different electronic elements 14b may be formed of the same conductive layer, but not limited thereto. In some embodiments, the electronic elements 14b of FIG. 8 may be replaced by the electronic elements of the above embodiments.

In the embodiment of FIG. 8, the electronic unit 14 may optionally include a light shielding pattern LS disposed on the encapsulation layer 14c, and the light shielding pattern LS may correspond to the insulating layer 40 in the top view direction TD, but not limited thereto. When the light shielding pattern LS includes metal, the light shielding pattern LS may be used as a touch pattern for sensing touching object. In some embodiments, the electronic unit 14 may further include an insulating layer 14e disposed between the light shielding pattern LS and the planarization layer 14d and between the dam structures 48 and the planarization layer 14d, but not limited thereto. In some embodiments, other parts of the electronic device 1 in FIG. 8 may adopt the above-mentioned or following embodiments and will not be described in detail here.

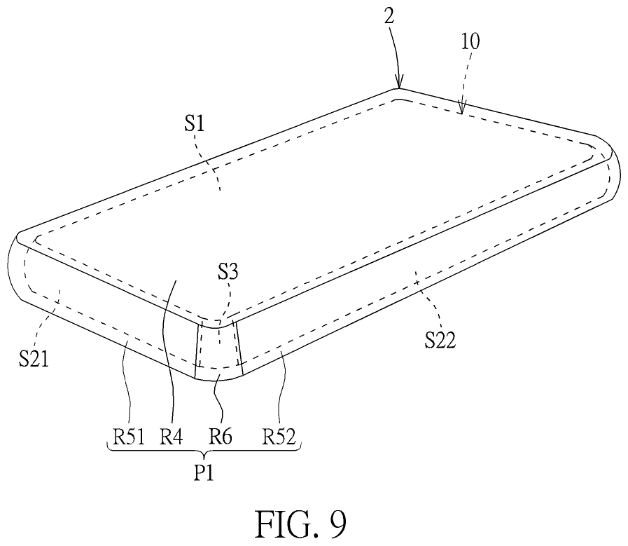

Refer to FIG. 9, which schematically illustrates a side view of an electronic device installed on an object according to a second embodiment of the present disclosure. As shown in FIG. 9, the object 10 may have a front surface S1, two curved side surfaces S21, two curved side surfaces S22, and four corner surfaces S3. The curved side surfaces S21, the curved side surfaces S22, and the corner surfaces S3 may constitute a side surface of the object 10. The object 10 may be, for example, a handheld device, including a mobile phone, a tablet, or other suitable devices. For example, in the case that the electronic device 2 is a display device, the curved side surfaces S21 may be left and right sides of the object 10, and the curved side surfaces S22 may be upper and lower sides of the object 10 when the object 10 is in use.

The electronic device 2 of this embodiment may, for example, be disposed on the front surface S1 and the side surface of the object 10. For example, the first portion P1 of the electronic device 2 may include a planar region R4, two curve regions R51, two curve regions R52, and four corner regions R6, wherein the curve regions R51 are disposed on upper and lower sides of the planar region R4, the curve regions R52 are disposed on left and right sides of the planar region R4, and one of the corner regions R6 is disposed between one of the curve regions R51 and one of the curve regions R52 adjacent to each other. The planar region R4, the curve regions R51, the curve regions R52, and the corner regions R6 may be attached to the front surface S1, the curved side surfaces S21, the curved side surfaces S22, and the corner surfaces S3, respectively, so that the electronic device 2 may surround the side surface of the object 10. Since the curve regions R51, the curve regions R52, and the corner regions R6 may be provided on the curved side surfaces S21, the curved side surfaces S22, and the corner surfaces S3, respectively, they may have non-planar surfaces. As an example, the planar region R4, the curve regions R51 and the curve regions R52 may each have a Gaussian curvature of 0, while the corner regions R6 may have Gaussian curvatures not equal to 0. In the present disclosure, the term “the corner region R6 with the Gaussian curvature not equal to 0” means that the corner region R6 is a region having a spherically curved surface. For example, the Gaussian curvature of the corner region R6 may be greater than 0. The method of obtaining the Gaussian curvature referred to in the present disclosure may, for example, includes scanning the surface of the object 10 to form a 3D model and then analyzing it to obtain an objective value of the Gaussian curvature of the appearance of the object 10 by using a scanning device and 3D analysis software (e.g., Geomagic Design X 3D or other suitable software, but not limited thereto). Accordingly, the Gaussian curvature of the first portion P1 on the object 10 may be obtained.

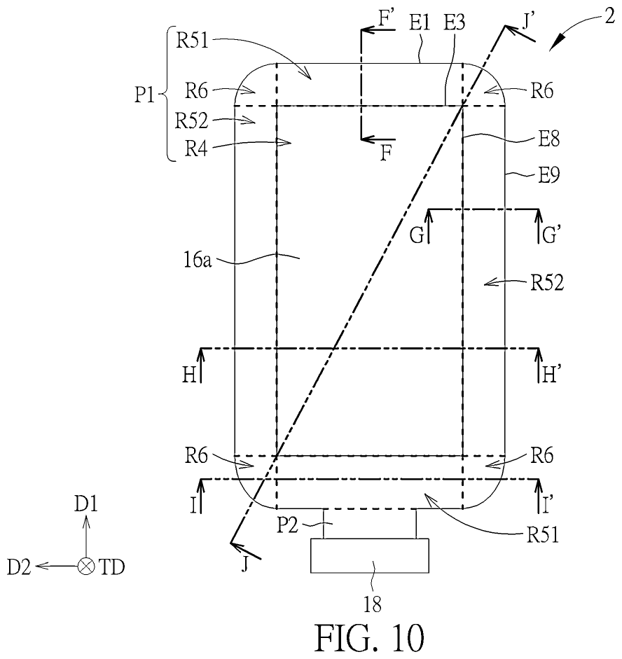

Refer to FIG. 10, which schematically illustrates a top view of the electronic device according to the second embodiment of the present disclosure in the flattened state. As shown in FIG. 10, in the electronic device 2 of this embodiment, the first layer 16a may cover the planar region R4 and may not be disposed on the curve regions R51, the curve regions R52, and the corner regions R6 of the first portion P1, so that the first layer 16a may not be disposed on a curved surface. Accordingly, damage to the first layer 16a may be reduced. In this case, the first layer 16a may not cover the second portion P2, but not limited thereto. In the present disclosure, an element “cover” another element may refer to the element overlapping the another element in the top view direction TD of the electronic device 2.

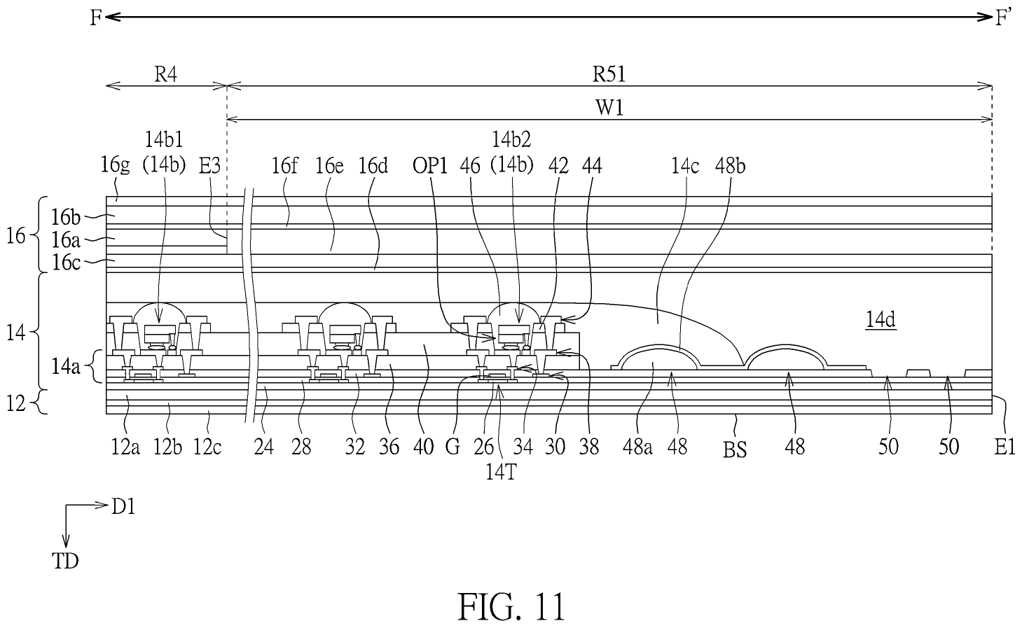

It should be noted that the second portion P2 and the circuit board 18 of this embodiment may be similar to the second portion P2 and the circuit board 18 of FIG. 2, and the second portion P2 may be bent to the backside (e.g., the backside BS of FIG. 11) of the first portion P1 while assembling the electronic device 2. Thus, the second portion P2 and the circuit board 18 may refer to the above contents and will not be detailed herein.

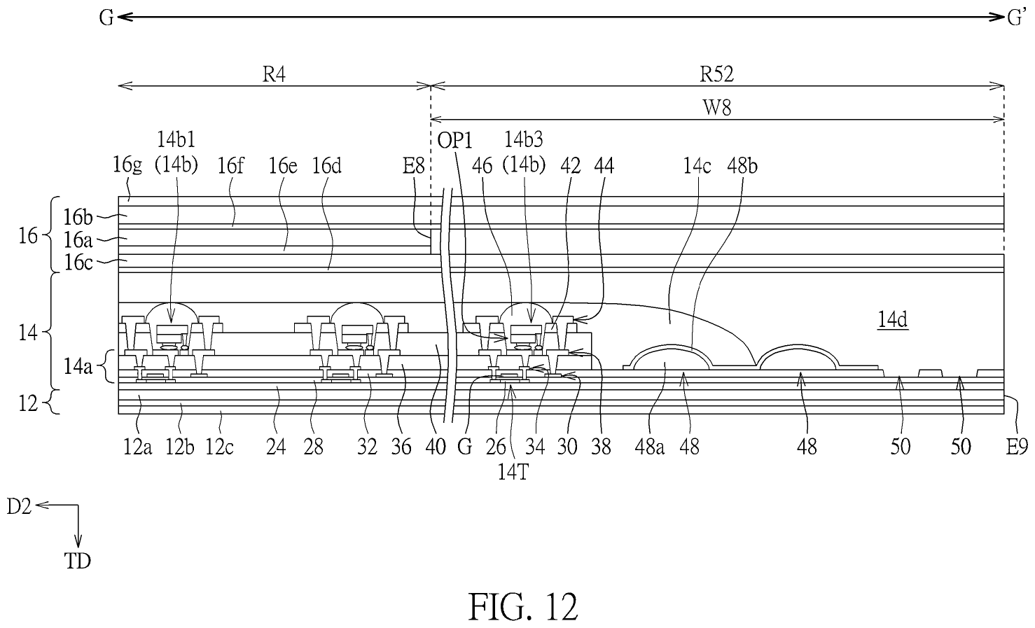

Refer to FIG. 11 and FIG. 12. FIG. 11 schematically illustrates a cross-sectional view taken along a line F-F′ of FIG. 10, and FIG. 12 schematically illustrates a cross-sectional view taken along a line G-G′ of FIG. 10. As shown in FIG. 10 to FIG. 12, since the edge E1 is the edge of the first portion P1 away from the curve region R51 of the circuit board 18, and the edge E9 is an edge of one of the curve regions R51 of the first portion P1, the edge E1 and the edge E9 may correspond to an upper curved side surface and a right curved side surface (or left curved side surface) of the object 10 respectively. In the embodiment of FIG. 10 to FIG. 12, the first layer 16a may be retreated from the edge E1 of the first portion P1 by the distance W1 and retreated from another edge E9 of the first portion P1 by a distance W8, and the distance W1 is not equal to the distance W8. For example, the distance W1 may be greater than the distance W8, so that parts of the electronic device 2 adjacent to the left curved side surface and the right curved side surface of the object 10 may be covered with more parts of the first layer 16a. Accordingly, image quality from the parts of the electronic device 2 adjacent to the left curved side surface and the right curved side surface of the object 10 may be improved.

In the embodiment of FIG. 11, when the first layer 16a does not cover the curve region R51, the electronic elements 14b may include at least one first electronic element 14b1 and at least one second electronic element 14b2, wherein the first electronic element 14b1 may be disposed on the planar region R4, and the second electronic element 14b2 may be disposed on one of the curve regions R51. In the embodiment of FIG. 12, when the first layer 16a does not cover the curve regions R52, the electronic elements 14b may include at least one first electronic element 14b1 and at least one second electronic element 14b2, wherein the first electronic element 14b1 may be disposed on the planar region R4, and the second electronic element 14b2 may be disposed on one of the curve regions R52. In some embodiments, the electronic elements 14b may optionally not be disposed on the curve regions R51 and/or the curve regions R52. In some embodiments, other parts of the electronic device 2 may be similar to or the same as the above-mentioned embodiments and may refer to the above-mentioned or following embodiments, and they are not detailed again herein.

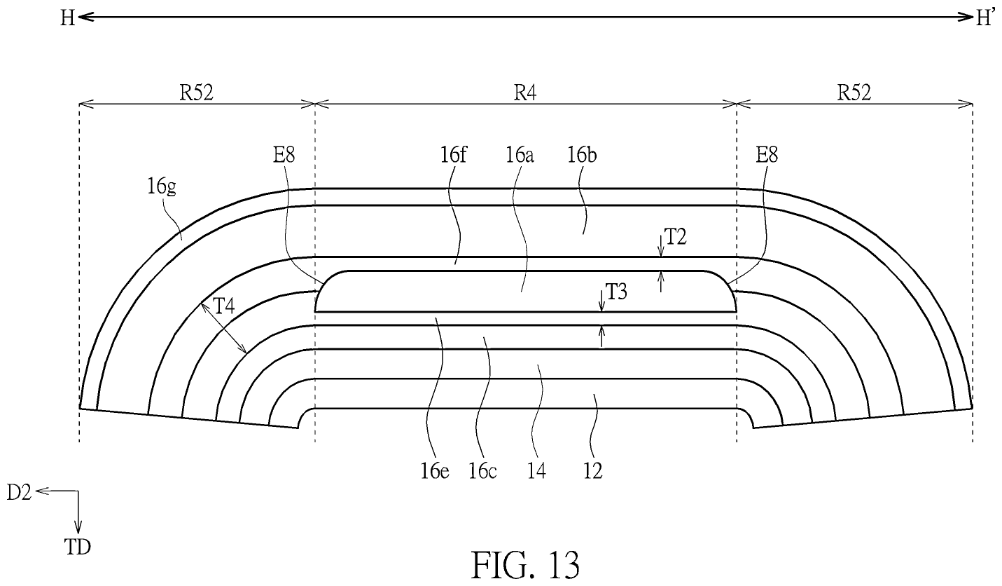

Refer to FIG. 13, which schematically illustrates cross-sectional view of an electronic device taken along a line H-H′ of FIG. 10 according to some embodiments of the present disclosure. The electronic device shown in FIG. 13 may, for example, be in a state of being attached to the object. As shown in FIG. 13, in some embodiments, the adhesive 16f and the adhesive 16e may extend into the curve region R52, so that the adhesive 16f and the adhesive 16e may cover at least one edge of the first layer 16a (e.g., the edge E8) to reduce the crack damage of the first layer 16a. In this way, a total thickness T4 of the adhesive 16f and the adhesive 16e located in the planar region R4 (i.e., a sum of the thickness T2 of the adhesive 16f and the thickness T3 of the adhesive 16e) may be less than that of the adhesive 16f and the adhesive 16e located in the curve region R52. The total thickness of the adhesive 16f and the adhesive 16e may be obtained by measuring the total thickness of the adhesive 16f and the adhesive 16e in the top view direction TD after flattening the curve region R52.

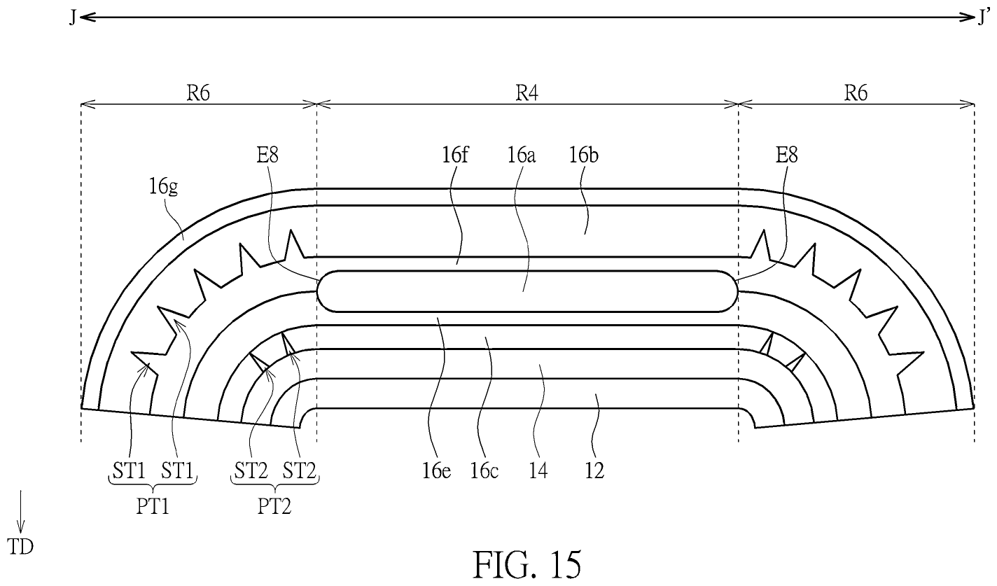

In some embodiments, the edge E8 of the first layer 16a may, for example, be a semi-curved surface (e.g., the edge E8 shown in FIG. 13) or a chamfered surface facing the second layer 16b, a semi-curved surface or a chamfered surface facing the third layer 16c, or a semi-circular curved surface (e.g., the edge E8 shown in FIG. 15), so that the stress on corners of the edges of the first layer 16a may be decreased to reduce cracks. This structure of the edge E8 of the first layer 16a may be adapted to any one of the above-mentioned and following embodiments. In some embodiments, other parts of the electronic device of FIG. 13 may be similar to or the same as the embodiment of FIG. 10 through FIG. 12 and may refer to the embodiments described above or below, and thus, they will not be repeated herein.

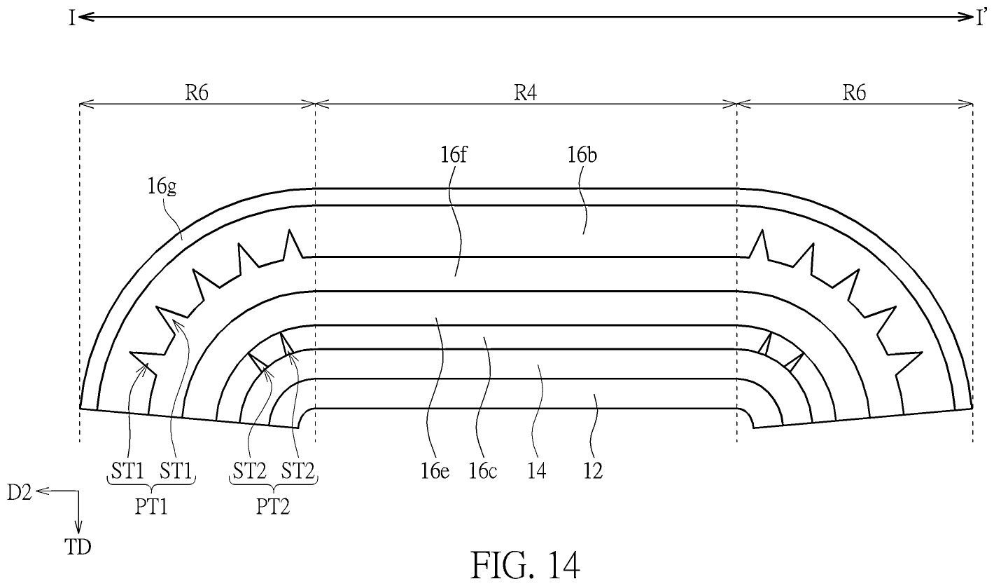

Refer to FIG. 14 and FIG. 15. FIG. 14 schematically illustrates a cross-sectional view of an electronic device taken along a line I-I′ of FIG. 10 according to some embodiments of the present disclosure, and FIG. 15 schematically illustrates a cross-sectional view of an electronic device taken along a line J-J′ of FIG. 10 according to some embodiments of the present disclosure. The electronic device shown in FIG. 14 and FIG. 15 may, for example, be in the state of being attached to the object. As shown in FIG. 14 and FIG. 15, in some embodiments, the second layer 16b may include a pattern PT1 disposed on the corner regions R6, and the third layer 16c may include a pattern PT2 disposed on the corner regions R6, wherein a depth of the pattern PT1 may be less than a depth of the pattern PT2. With this design, the electronic device 2 may have a greater bending range while being disposed on the corner surfaces of the object, so that it may conform to the surfaces of the object corresponding to the corner regions R6 (e.g., the corner surfaces S3 shown in FIG. 9). Since the pattern PT2 closer to the flexible substrate 12 has deeper depth, parts of the third layer 16c corresponding to the corner regions R6 may allow greater stretch and contraction, and conformity of the electronic device attached to the corner surfaces may be improved.

The pattern PT1 may include a plurality of microstructures ST1, and the microstructures ST1 may be grooves recessed into the second layer 16b from a surface of the second layer 16b facing the flexible substrate 12 or through holes penetrating the second layer 16b, but not limited thereto. The pattern PT2 may include a plurality of microstructures ST2, and the microstructures ST2 may be grooves recessed into the third layer 16c from a surface of the third layer 16c facing the flexible substrate 12 or through holes penetrating the third layer 16c, but not limited thereto. In the embodiment of FIG. 14 and FIG. 15, the pattern PT1 and the pattern PT2 may both be grooves, and a width of one of the grooves in a direction along a cross-sectional line (e.g., the first direction D1) may be less as a depth of the groove is greater. For example, a cross-sectional shape of the groove is an inverted V shape, but not limited thereto. In some embodiments, one of the grooves may have substantially uniform width in the direction along the cross-sectional line as the depth of the groove changes, but not limited thereto. In one embodiment, the adhesive 16f may be further disposed in the microstructure ST1, but not limited thereto.

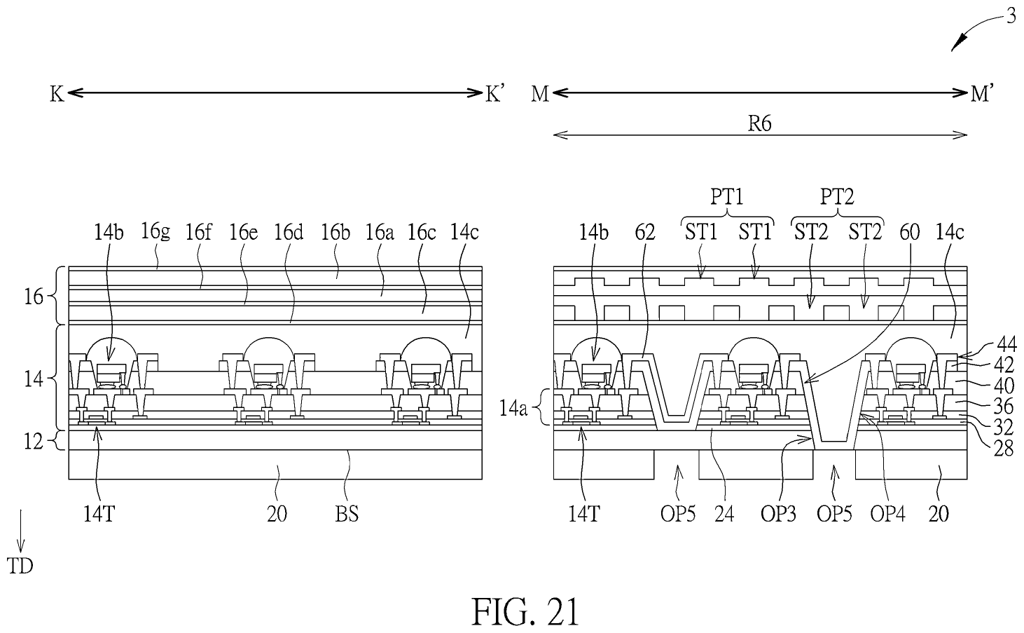

As shown in FIG. 14, a part of the electronic unit 14 may extend to be on one of the corner regions R6 of the flexible substrate 12. In other words, the electronic elements of the electronic unit 14 (e.g., the electronic elements 14b disposed on the corner region R6 shown in FIG. 21) may be disposed on the corner region R6, such that a part of the electronic device corresponding to the corner region may also display images, but not limited thereto. In some embodiments, other parts of the electronic device shown in FIG. 14 and FIG. 15 may be similar to or the same as the embodiment of FIG. 10 to FIG. 12 and may refer to the above-mentioned or following embodiments, so they are not detailed again herein.

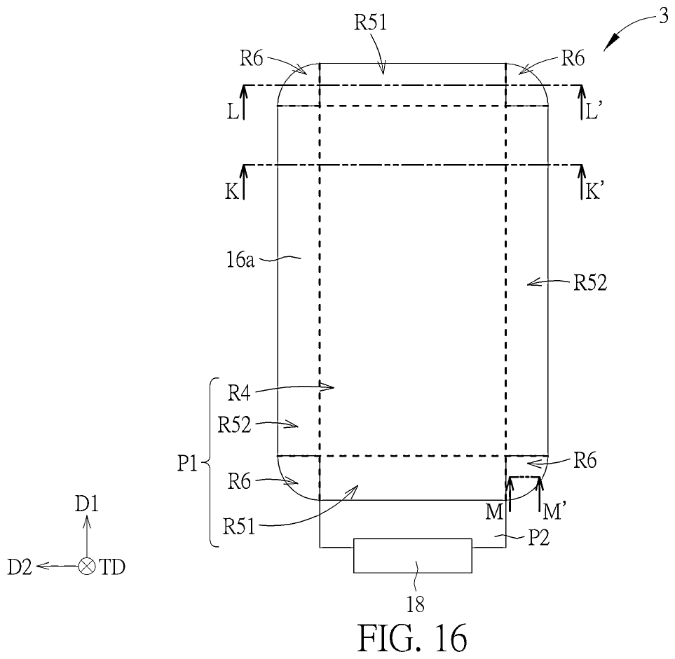

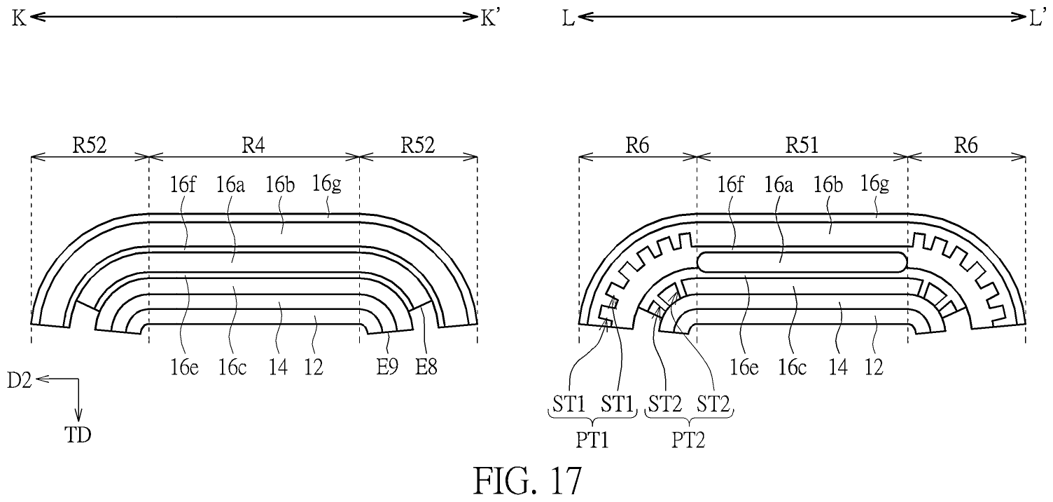

Refer to FIG. 16 and FIG. 17. FIG. 16 schematically illustrates a top view of an electronic device in the flattened state according to a third embodiment of the present disclosure, and FIG. 17 schematically illustrates cross-sectional views of the electronic device taken along a line K-K′ and a line L-L′ of FIG. 16 respectively according to the third embodiment of the present disclosure, in which the electronic device shown in FIG. 17 may, for example, be in the state of being attached to the object. As shown in FIG. 16 and FIG. 17, the electronic device 3 of this embodiment differs from the electronic device 2 of FIG. 10 in that the first layer 16a of this embodiment may cover the planar region R4, the curve regions R52 and the curve regions R51, and the first layer 16a may not cover the corner regions R6 of the flexible substrate 12. Since the Gaussian curvatures of the planar region R4, the curve regions R52 and the curve regions R51 of the flexible substrate 12 are 0, the stress on the first layer 16a disposed on the flexible substrate 12 may be decreased to reduce damage to the first layer 16a. Since the first layer 16a extends to the curve regions R52 and the curve regions R51, the display quality of parts of the electronic device 3 corresponding to the curve regions R52 and the curve regions R51 and/or protection of parts of the electronic unit 14 disposed on the curve regions R52 and the curve regions R51 may be improved. In some embodiments, besides the first layer 16a does not cover the corner regions R6, the first layer 16a may optionally not cover at least one of the curve regions R51 and/or at least one of the curve regions R52, but cover other curve regions R51 and/or curve regions R52, but not limited thereto.

As shown in FIG. 17, the first layer 16a may cover the curve regions R52 while being retreated from the edge E9 of the flexible substrate 12 by a distance. In other words, the edge E8 of the first layer 16a may not be aligned to the edge E9 of the flexible substrate 12. In some embodiments, the edge of the adhesive 16f and the corresponding edge of the adhesive 16e may not be aligned, but not limited thereto. Since the first layer 16a does not extend to the corner regions R6, the adhesive 16f and the adhesive 16e disposed on one of the corner regions R6 may contact each other and cover the edge of the first layer 16a located on the curve regions R51 (or the curve regions R52).

In the embodiment of FIG. 17, a cross-sectional shape of one of the microstructures ST1 of the pattern PT1 and a cross-sectional shape of one of the microstructures ST2 of the pattern PT2 in the direction along the cross-sectional line (e.g., the first direction D1) may be, for example, a rectangle or other suitable shape, but not limited thereto. In this case, the adhesive 16e may be disposed in the microstructure ST2, but not limited thereto. In some embodiments, other parts of the electronic device 3 of FIG. 16 and FIG. 17 may be similar to or the same as the embodiment of FIG. 10 to FIG. 12 and may refer to the embodiments described above or below, so that they will not be repeated herein.

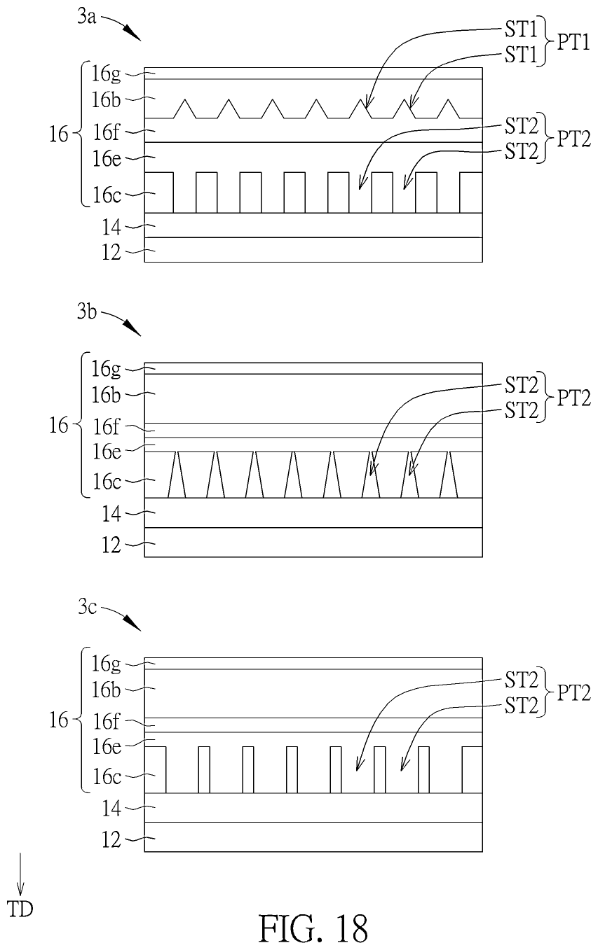

Refer FIG. 18, which schematically illustrates cross-sectional views of electronic devices in the flattened state according to some embodiments of the present disclosure. As shown in FIG. 18, in the cover 16 of the electronic device 3a, the cross-sectional shapes of one of the microstructures ST1 of the pattern PT1 and one of the microstructures ST2 of the pattern PT2 along the same cross-sectional direction may be different. For example, the cross-sectional shape of the groove of the microstructure ST1 is an inverted V shape, and the cross-sectional shape of the groove of the microstructure ST2 is a rectangle, but not limited thereto.

In the cover 16 of the electronic device 3b, the second layer 16b may not have the pattern PT1, and the third layer 16c may have the pattern PT2. In the electronic device 3b, the microstructures ST2 of the pattern PT2 may be through holes penetrating through the third layer 16c, and the adhesive 16e may be disposed in the through holes. The cross-sectional shape of one of the microstructures ST2 in the direction along the same cross-sectional line may be, for example, an inverted V shape or other suitable shapes. In some embodiments, one of the microstructures ST2 may be a groove that does not penetrate through the third layer 16c, but not limited thereto.

In the cover 16 of the electronic device 3c, when the second layer 16b may not have the pattern PT1, one of the microstructures ST2 of the third layer 16c may be a through hole penetrating through the third layer 16c. In this case, the adhesive 16e may be disposed in the through hole. The cross-sectional shape of the microstructure ST2 along the same cross-sectional direction may be, for example, a rectangle or other suitable shapes. In some embodiments, any of the covers 16 of the electronic device 3a, the electronic device 3b, and the electronic device 3c shown in FIG. 18 may be adapted to the embodiments described above or below.

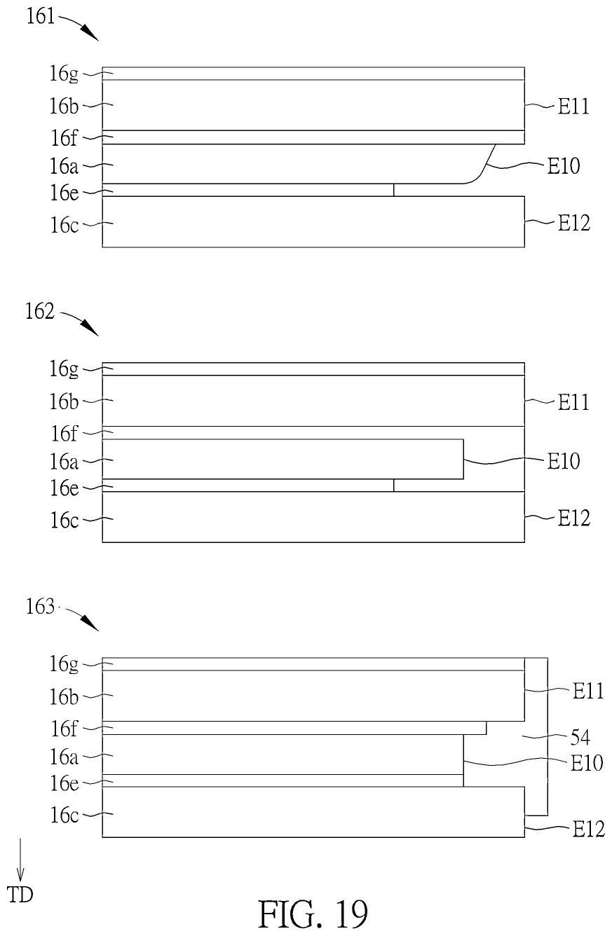

Refer to FIG. 19, which schematically illustrates cross-sectional views of parts of covers corresponding to one of the curve regions in the flattened state according to some embodiments of the present disclosure. As shown in FIG. 19, in a cover 161, an edge E10 of the first layer 16a, the corresponding edge of the adhesive 16f, and the corresponding edge of the adhesive 16e may not be aligned to each other. In one embodiment, the edge of the adhesive 16e may be retreated from the edge E10 of the first layer 16a, but not limited thereto.

In a cover 162, when the edge of the adhesive 16e is retreated from the edge E10 of the first layer 16a by a distance, the adhesive 16f may extend to be between the first layer 16a and the third layer 16e to protect the edge E10 of the first layer 16a.

In a cover 163, when the edge E8 of the first layer 16a is retreated from the edge E11 of the second layer 16b by a distance, the cover 163 may further include an encapsulant 54 disposed on the edge E10 of the first layer 16a to protect the first layer 16a. For example, the encapsulant 54 may fill a cavity formed by the retreat of the first layer 16a, and the encapsulant 54 may optionally extend to be on the edge E11 of the second layer 16b and/or the edge E12 of the third layer 16c.

Refer FIG. 20, which schematically illustrates cross-sectional views of parts of covers corresponding to one of the curve regions in the flattened state according to some embodiments of the present disclosure. As shown in FIG. 20, a cover 164 and a cover 165 may not include the third layer. In this case, the first layer 16a may be directly attached to the electronic unit (e.g., the electronic unit 14 of any of the embodiments mentioned above or below). In the cover 165, the adhesive 16f may further cover the edge E10 of the first layer 16a to protect the first layer 16a.

In some embodiments, any of the cover 161, the cover 162 and the cover 163 of FIG. 19 and the cover 164 and the cover 165 of FIG. 20 may be adapted to the embodiments described above or below.

Refer to FIG. 21, which schematically illustrates cross-sectional views of parts of an electronic device in the flattened state respectively taken along a line K-K′ and a line M-M′ of FIG. 16 according to some embodiments of the present disclosure. As shown in FIG. 21, the electronic device 3 of some embodiments differs from the embodiment of FIG. 11 and FIG. 12 in that the first layer 16a may extend to be on one of the curve regions of the flexible substrate 12. Since other parts of the flexible substrate 12, the electronic unit 14, and the cover 16 corresponding to the cross-sectional line K-K′ may be similar to or the same as the embodiment of FIG. 11 and FIG. 12 and may refer to the contents mentioned above, so that they are not repeated herein.

As shown in FIG. 21, one of the corner regions R6 of the flexible substrate 12 may have a patterned structure. For example, the corner region R6 may have an opening OP3, wherein a size of the opening OP3 may change as the flexible substrate 12 is stretched, so that the corner region R6 may, for example, have a Poisson's ratio less than 0, which helps a part of the electronic device 3 corresponding to the corner region R6 to conform to the corner surface of the object.

In the embodiment of FIG. 21, the insulating layer 24, the insulating layer 28, the insulating layer 32, the insulating layer 36 and the insulating layer 40 may have an opening OP4 corresponding to the opening OP3 of the corner region R6 to help a part of the electronic device 3 corresponding to the corner region R6 to stretch or deform. The insulating layer 42 may extend into the opening OP4 and the opening OP3, and the encapsulation layer 14c may be disposed in the opening OP4. In some embodiments, the electronic unit 14 may include a plurality of block structures 60 that may be disposed on the corner region R6. In other words, layers on the corner region R6 may be patterned to form the block structures 141. Each block structure 60 may include, for example, the insulating layer 24, the circuit layer 14a, the insulating layer 40, and the electronic element 14b. The insulating layer 42 may extend to be between the block structures 60 and may contact the corner region R6, for example. Furthermore, the conductive layer 44 may include traces 62 disposed on the insulating layer 42 and extend to the block structures 60 to electrically connect different block structures 60. In some embodiments, the number of electronic elements 14b in each block structure 60 may be at least one, but not limited thereto.

As shown in FIG. 21, the electronic device 3 may further include a supporting film 20 disposed on the backside BS of the flexible substrate 12. The supporting film 20 may optionally include openings OP5 to help to stretch a part of the electronic device 3 corresponding to the corner region R6. In some embodiments, other parts of the electronic device 3 shown in FIG. 21 may be similar to or the same as the embodiment of FIG. 16 and FIG. 17 and may be referred to the content mentioned above, and they will not be repeated herein.

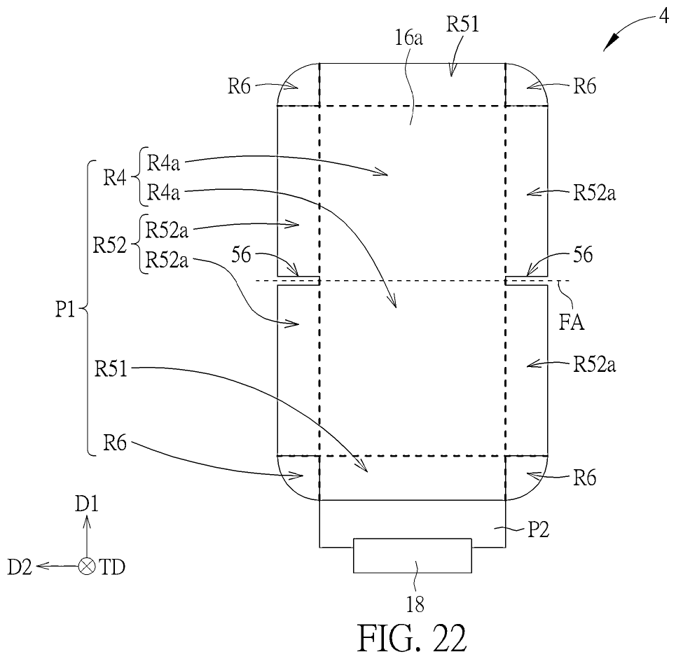

FIG. 22 schematically illustrates a top view of an electronic device in the flattened state according to a fourth embodiment of the present disclosure. As shown in FIG. 22, the electronic device 4 of this embodiment differs from the electronic device 3 of FIG. 16 in that the electronic device 4 may have a folding axis FA, such that the electronic device 4 may be folded along the folding axis FA. In the embodiment of FIG. 22, the electronic device 4 may include a recess 56 disposed in the curve region R52, and the recess 56 may separate the curve region R52 into two sub-curve regions R52a. Layers (e.g., the electronic unit and the cover 16 including the first layer 16a) disposed on the different sub-curve regions R52a are also separated into two parts. When the electronic unit 4 is folded along the folding axis FA, two parts R4a of the planar region R4 may be folded in a direction opposite to the top view direction TD, i.e., in a manner that surfaces of the two parts R4a facing the electronic unit face each other. Since the curve region R52a is attached to the object in a manner that the curved region 52a is bent toward the top view direction TD, a problem that the sub-curve region R52a unable to be folded may be avoided through the recess 56. In some embodiments, other parts of the electronic device 4 of FIG. 22 may adopt any of the above embodiments and may be referred to the contents mentioned above, and they will not be repeated herein.

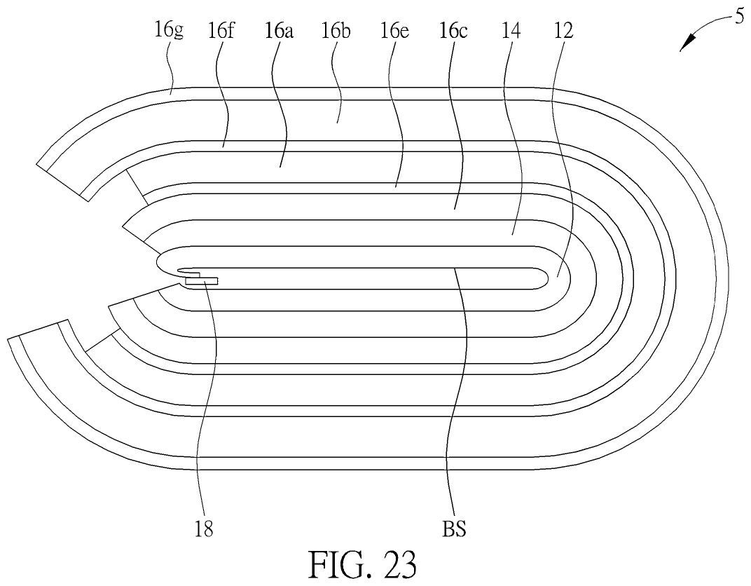

FIG. 23 schematically illustrates a side view of an electronic device according to a fifth embodiment of the present disclosure. As shown in FIG. 23, two parts of the electronic device 5 of this embodiment may be folded and fixed in a manner that parts of the backside BS of the flexible substrate 12 faces each other to form a double-sided electronic device, such as a double-sided display device. In some embodiments, the electronic device 5 may be fixed by curling the backside BS of the flexible substrate 12 inward to form a pillar-shaped or wraparound electronic device, such as a pillar-shaped or wraparound display device, so that the electronic device 5 may display images toward multiple directions. Since other parts of the electronic device 5 in FIG. 23 may be the same as or similar to any of the above embodiments and may refer to the contents mentioned above, so that they will not be described in detail here.

In summary, in the electronic device of the present disclosure, the first layer is retreated from one edge of the first portion by a distance and retreated from another edge of the first portion by another distance, and the distance may be different from the another distance, so that cracks in the first layer due to bending of the second portion may be decreased to reduce crack damage to the first layer. In this case, the first layer may be allowed to be disposed in the electronic device to improve the display quality of the electronic device and/or improve the reliability of the electronic device. Moreover, the first layer may be disposed on the folding region or the curve regions of the flexible substrate to improve the display quality of non-planar part of the electronic device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a flexible substrate having a first portion and a second portion;
an electronic unit disposed on the flexible substrate; and
a cover disposed on the electronic unit and comprising a first layer;
wherein the first layer is retreated from an edge of the first portion by a first distance and retreated from an edge of the second portion by a second distance, and the second distance is different from the first distance.

2. The electronic device according to claim 1, further comprising a circuit board bonded to the second portion, and the second distance is greater than the first distance.

3. The electronic device according to claim 1, wherein a ratio of the second distance to the first distance is ranged from 1.5 to 1000.

4. The electronic device according to claim 1, wherein the cover further comprises a second layer disposed on the first layer.

5. The electronic device according to claim 4, wherein the first layer is retreated from an edge of the second layer by a third distance ranged from 30 μm to 600 μm.

6. The electronic device according to claim 4, wherein the first layer comprises an inorganic material, and the second layer comprises an organic material.

7. The electronic device according to claim 4, wherein the cover further comprises a coating layer disposed on the second layer.

8. The electronic device according to claim 1, wherein a thickness of the first layer is less than or equal to 100 μm.

9. The electronic device according to claim 1, wherein the first layer is glass.

10. The electronic device according to claim 1, wherein the second portion is bent to a backside of the first portion.

11. The electronic device according to claim 10, wherein the first portion comprises a planar region and a first curve region, and the electronic unit comprises a first electronic element on the planar region and a second electronic element on the first curve region.

12. The electronic device according to claim 11, wherein the first layer covers the planar region and does not cover the first curve region.

13. The electronic device according to claim 11, wherein the first layer covers the planar region and the first curve region.

14. The electronic device according to claim 11, wherein the first portion further comprises a second curve region and a corner region between the first curve region and the second curve region, the electronic unit further comprises a third electronic element on the corner region, and the corner region has a Gaussian curvature not equal to zero.

15. The electronic device according to claim 14, wherein the first layer covers the planar region, the first curve region and the second curve region, and does not cover the corner region.

16. The electronic device according to claim 14, wherein the first layer covers the planar region and does not cover the first curve region, the second curve region and the corner region.

17. The electronic device according to claim 14, wherein the cover further comprises a second layer on the first layer and a third layer under the first layer, the second layer comprises a first pattern in the corner region, the third layer comprises a second pattern in the corner region, and a depth of the first pattern is less than a depth of the second pattern.

18. The electronic device according to claim 11, wherein the cover further comprises a second layer on the first layer and a third layer under the first layer, the second layer is attached to the first layer by a first adhesive, the third layer is attached to the first layer by a second adhesive.

19. The electronic device according to claim 18, wherein a total thickness of the first adhesive and the second adhesive on the planar region is less than a total thickness of the first adhesive and the second adhesive on the first curve region.

20. The electronic device according to claim 1, wherein the first portion comprises a folding region and a non-folding region, the first layer is retreated from an edge of the folding region by a fourth distance and retreated from an edge of the non-folding region by a fifth distance, wherein the fourth distance is greater than the fifth distance.
